(19) United States
(12) Patent Application Publication
(10) Pub. No.: US 2022/0416112 A1
(43) Pub. Date: Dec. 29, 2022

(54) CONTROL OF SURFACE MORPHOLOGY OF SPALLED (110) III-V SUBSTRATE SURFACES

(71) Applicants: Alliance for Sustainable Energy, LLC, Golden, CO (US); Colorado School of Mines, Golden, CO (US)

(72) Inventors: Kevin Louis SCHULTE, Denver, CO (US); Corinne Evelyn PACKARD, Lakewood, CO (US); Jason Michael CHENENKO, Hampton, VA (US)

(21) Appl. No.: 17/809,841

(22) Filed: Jun. 29, 2022

Related U.S. Application Data
(60) Provisional application No. 63/216,391, filed on Jun. 29, 2021.

(51) Int. Cl. H01L 31/18; H01L 31/0304; H01L 31/036; H01L 31/0735

(52) U.S. Cl. CPC H01L 31/184; H01L 31/0304; H01L 31/036; H01L 31/0735; H01L 31/1892

(57) ABSTRACT

The present disclosure relates to a composition that includes a III-V planar substrate having a surface aligned with and parallel to a reference plane, where the surface includes a plurality of terraces, each terrace includes a first surface positioned between a first boundary and a second boundary, each boundary is substantially parallel to the other boundaries and positioned substantially parallel to the reference plane, and each terrace is separated from an adjacent terrace by a second surface positioned between the second boundary of the terrace and the first boundary of the adjacent terrace.

### CROSS-REFERENCE TO RELATED APPLICATIONS

This application claims priority from U.S. Provisional Patent Application No. 63/216,391 filed on Jun. 29, 2021, the contents of which are incorporated herein by reference in their entirety.

### CONTRACTUAL ORIGIN

This invention was made with government support under Contract No. DE-AC36-08GO28308 awarded by the Department of Energy. The government has certain rights in the invention.

### BACKGROUND

Substrates, usually GaAs, are the most expensive component in III-V solar cells. Spalling is a method by which device layers deposited onto substrates can be removed from the substrates, with the substrate preserved, enabling its recycle and reuse for future device growth. Spalling of the more common (100) substrate crystal orientation results in an undesirable “saw-toothed” surface with triangular facets; facets bound by the (110) or (211) planes, which have some of the weakest bond energies of any GaAs plane. Thus, there remains a need for improved spalling methods capable of producing substrate surfaces better suited for depositing semiconductor materials and for reliable recovery and reuse of the substrates.

### SUMMARY

An aspect of the present disclosure is a composition that includes a III-V planar substrate having a surface aligned with and parallel to a reference plane, where the surface includes a plurality of terraces, each terrace includes a first surface positioned between a first boundary and a second boundary, each boundary is substantially parallel to the other boundaries and positioned substantially parallel to the reference plane, and each terrace is separated from an adjacent terrace by a second surface positioned between the second boundary of the terrace and the first boundary of the adjacent terrace. Further, for each terrace, the first boundary is positioned approximately at a distance, H, relative to its second boundary in a first direction that is orthogonal to the reference plane and the first boundary is positioned approximately at a distance, W, relative to the second boundary in a second direction parallel to the reference plane and orthogonal to the first direction. Finally, each terrace is positioned in a plane that is positioned at an angle, a, relative to the reference plane, each terrace has a surface roughness of less than 1 nm, as measured by atomic force microscopy, 0 μm≤H≤3 μm, and 1 μm<W≤1 mm.

In some embodiments of the present disclosure, H may vary between ±20% relative to the average value of H. In some embodiments of the present disclosure, W may vary between ±15% relative to the average value of W. In some embodiments of the present disclosure, the III-V planar substrate may have a zinc blende crystal structure. In some embodiments of the present disclosure, the III-V planar substrate may be constructed of at least one of GaAs, GaP, InAs, AlAs, AlP, and/or InP. In some embodiments of the present disclosure, the III-V planar substrate may be constructed of a pseudo-binary combinations of at least one of GaAs, GaP, InAs, AlAs, AlP, and/or InP. In some embodiments of the present disclosure, α may be between less than 5°. In some embodiments of the present disclosure, α may be between less than 3°. In some embodiments of the present disclosure, each terrace may be positioned substantially in at least one of the (110) plane, the (111) plane, the (211) plane, and/or the (311) plane. In some embodiments of the present disclosure, 30 μm<W≤100 μm.

An aspect of the present disclosure is a method that includes depositing a device layer onto a planar substrate, depositing a stressor layer onto the device layer, and applying a directional force orthogonal to the reference plane and moving in a direction that is parallel to the reference plane. Further, the planar substrate is oriented to a plane is that is positioned at an angle, α, relative to a reference plane, and the applying results in the separating of the device layer from at least a portion of the planar substrate. In some embodiments of the present disclosure, the planar substrate may be substantially oriented in at least one of the (110) plane, the (111) plane, the (211) plane, and/or the (311) plane.

In some embodiments of the present disclosure, the planar substrate may be composed of a III-V alloy having a zinc blende crystal structure. In some embodiments of the present disclosure, the angle α may be less than 5°. In some embodiments of the present disclosure, the angle α may be less than 3°. In some embodiments of the present disclosure, the planar substrate may be substantially oriented in the (110) plane and the moving of the directional force may be substantially in the [1-10] direction. In some embodiments of the present disclosure, the separating of the device layer may occur at thickness, t, of less than 10 μm into the planar substrate relative to an interface created by the planar substrate and the device layer. In some embodiments of the present disclosure, the thickness into the planar substrate may be 3 μm≤t<10 μm. In some embodiments of the present disclosure, the applying may be achieved using a roller configured with an adhesive. In some embodiments of the present disclosure, the method may further include recovering and recycling the separated planar substrate for at least one additional depositing of a device layer.

### BRIEF DESCRIPTION OF DRAWINGS

Some embodiments are illustrated in referenced figures of the drawings. It is intended that the embodiments and figures disclosed herein are to be considered illustrative rather than limiting.

FIGS. 1 and 2 illustrate a zinc blende crystal structure and some of notation and nomenclature used herein, according to some embodiments of the present disclosure.

FIG. 3A illustrates a device constructed using a III-V substrate oriented relative to the (110) plane and having a positive offcut relative to that plane, according to some embodiments of the present disclosure.

FIG. 3B illustrates nomenclature and notation used to indicate spalling directions relative to a substrate surface oriented to the (110) plane, according to some embodiments of the present disclosure.

FIG. 4 illustrates a method for producing multiple device layers by recovering and recycling a substrate layer, according to some embodiments of the present disclosure.

FIG. 5A illustrates an upright device structure used to evaluate the methods and substrates described herein, according to some embodiments of the present disclosure.

FIG. 5B illustrates (Panel a) a Nomarski micrograph of the post spall surface morphology of a (110) GaAs wafer; and (Panel b) a Nomarski micrograph of the surface after growth of the upright device structure on the previously spalled wafer

FIG. 5C illustrates (Panel a) external quantum efficiency measurements of upright devices grown on new and previously spalled (110) wafers; and (Panel b) AM1.5G light current-density voltage measurements of these devices, according to some embodiments of the present disclosure.

FIG. 6 illustrates exfoliation of an epitaxial device from a parent substrate via controlled spalling, according to some embodiments of the present disclosure.

FIG. 7A illustrates a diagram of an exemplary spalling process for III-V substrates (e.g., (110) GaAs wafers), according to some embodiments of the present disclosure.

FIG. 7B illustrates (Panel a) a spalled (110) GaAs wafer (i.e., substrate) and Panel (b) a spalled (110) GaAs film, according to some embodiments of the present disclosure.

FIG. 8 illustrates confocal laser scanning micrographs of spall morphologies in (110) GaAs by offcut angle and spall direction, according to some embodiments of the present disclosure; Panel (a): 3° offcut with spalling towards the [11-1] plane; Panel (b): 3° B, [00-1] spall; Panel (c): On-axis, [1-10] spall; and Panel (d): On-axis, [00-1] spall.

FIG. 9A illustrates an optical image of a wafer (i.e., substrate) post spall, which defines the primary crystallographic directions of note for a (110)-oriented wafer, according to some embodiments of the present disclosure.

FIG. 9B illustrates scanning electron microscopy (SEM) images of resultant surface morphologies after using the spalling methods described herein, according to some embodiments of the present disclosure. Panel (a) illustrates SEM images of a (110)-oriented wafer with a 3° offcut with spalling towards the [111] plan in the [1-10] direction at two magnifications and Panel (b) illustrates SEM images of a (110) wafer with a 3° A offcut spalled in the [00-1] direction at two magnifications, according to some embodiments of the present disclosure.

FIG. 9C illustrates SEM images of a (110)-oriented wafer with nominally no offcut with a misorientation not greater than +or −0.5° off (110) spalled in the [1-10] direction at two magnifications, according to some embodiments of the present disclosure.

FIGS. 10A and 10B illustrate laser scanning confocal microscopy images of GaAs surfaces attained using methods described herein, according to some embodiments of the present disclosure.

FIG. 11 illustrates SEM images of a solar cell manufactured using methods described herein, according to some embodiments of the present disclosure.

REFERENCE NUMERALS

| | | |
|---|---|---|
| 100 | . . . | device |
| 110 | . . . | (abc)-oriented substrate layer |
| 120 | . . . | first boundary |
| 122 | . . . | second boundary |
| 130 | . . . | terrace |
| 132 | . . . | first surface |
| 134 | . . . | second surface |
| 140 | . . . | surface facet |
| α | . . . | offcut |
| W | . . . | terrace width |
| H | . . . | peak-to-valley height |
| 200 | . . . | method |
| 205 | . . . | planar substrate |
| 210 | . . . | aligning planar substrate |
| 220 | . . . | adjusting planar substrate |
| 230 | . . . | depositing of device layer onto |
| | | a planar substrate |
| 235 | . . . | device layer |
| 240 | . . . | depositing of stressor layer |
| | | onto device layer |
| 245 | . . . | stressor layer |
| 250 | . . . | applying a directional force |
| 260 | . . . | separating the device layer from |
| | | the planar substrate |
| 245 | . . . | stressor layer |

### DETAILED DESCRIPTION

The embodiments described herein should not necessarily be construed as limited to addressing any of the particular problems or deficiencies discussed herein. References in the specification to “one embodiment”, “an embodiment”, “an example embodiment”, “some embodiments”, etc., indicate that the embodiment described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

As used herein the term “substantially” is used to indicate that exact values are not necessarily attainable. By way of example, one of ordinary skill in the art will understand that in some chemical reactions 100% conversion of a reactant is possible, yet unlikely. Most of a reactant may be converted to a product and conversion of the reactant may asymptotically approach 100% conversion. So, although from a practical perspective 100% of the reactant is converted, from a technical perspective, a small and sometimes difficult to define amount remains. For this example of a chemical reactant, that amount may be relatively easily defined by the detection limits of the instrument used to test for it. However, in many cases, this amount may not be easily defined, hence the use of the term “substantially”. In some embodiments of the present invention, the term “substantially” is defined as approaching a specific numeric value or target to within 20%, 15%, 10%, 5%, or within 1% of the value or target. In further embodiments of the present invention, the term “substantially” is defined as approaching a specific numeric value or target to within 1%, 0.9%, 0.8%, 0.7%, 0.6%, 0.5%, 0.4%, 0.3%, 0.2%, or 0.1% of the value or target.

As used herein, the term “about” is used to indicate that exact values are not necessarily attainable. Therefore, the term “about” is used to indicate this uncertainty limit. In some embodiments of the present invention, the term “about” is used to indicate an uncertainty limit of less than or equal to ±20%, ±15%, ±10%, ±5%, or ±1% of a specific numeric value or target. In some embodiments of the present invention, the term “about” is used to indicate an uncertainty limit of less than or equal to ±1%, ±0.9%, ±0.8%, ±0.7%, ±0.6%, ±0.5%, ±0.4%, ±0.3%, ±0.2%, or ±0.1% of a specific numeric value or target.

Among other things, the present disclosure relates to methods that provide a consistent and reliable separation of a device layer (or layers) that was deposited onto a substrate, resulting in a separate device layer and a separate substrate layer. The device layer may then be subsequently processed and at least a portion of the original substrate may then be recycled and reused to produce additional device layers. As shown herein, manufacturing costs for III-V devices may be reduced by depositing (e.g., by hydride vapor phase epitaxy (HVPE)) III-V device layers onto a (110)-oriented GaAs substrate layer, after which the device layers may be removed by controlled spalling on the (110) plane of the device in a specific direction (e.g. [1-10]), resulting in the separation of the device layers from the (110)-oriented GaAs substrate. Although, the focus of the present disclosure is the depositing of III-V device layers onto III-V substrate layers, device layers constructed of other crystalline semiconducting materials may also fall within the scope of the present disclosure. Similarly, although GaAs is described herein in detail, substrate layers constructed of other III-V alloys may also fall within the scope of the present disclosure.

As described herein, spalling is a method by which III-V device layers can be exfoliated (i.e., separated, removed) from the parent substrate, enabling reuse of the substrate with potentially minimal surface re-preparation. This provides improved economics over state-of-the-art substrate recovery techniques such as epitaxial liftoff (ELO). Spalling of the most common GaAs substrate orientation, (100), results in the formation of surface facets, defined as large regular features with a low index crystallographic orientation, i.e. (110) or (211), having peak-to-valley characteristic length/height dimensions between 10 μm and 15 μm, which require polishing or epitaxial smoothing before devices can be re-grown on the substrate, thereby limiting the viability of this technology. On the other hand, as shown herein, spalling (i.e., separating) of device layers from preferentially oriented substrates (e.g., 110-oriented substrates) can successfully recover the substrates having surfaces suitable for the regrown of additional device layers and requiring no or minimal surface preparation before the depositing of the new device layers. Therefore, the methods described herein relate to the spalling (i.e., removing) of III-V device layers from substrates having an (110)-orientation, followed by the growth and regrowth of new device layers onto the recovered and recycled (110)-oriented substrates. In some embodiments of the present disclosure, device layers may be deposited by dynamic hydride vapor phase epitaxy (D-HVPE), a growth technology with the potential for, among other things, manufacturing cost savings.

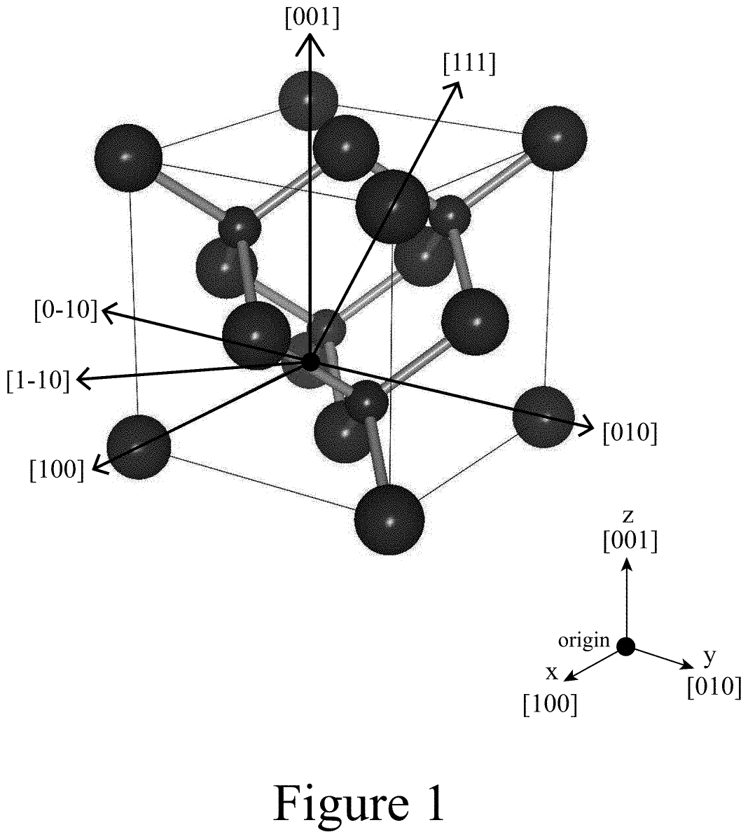

In some embodiments of the present disclosure, the methods and resultant compositions and devices may apply to any III-V alloy having a zinc blende crystal structure. Examples of III-V alloys having a zinc blende crystal structure include GaAs, GaP, InAs, AlAs, AlP, InP, and pseudo-binary combinations of these binary alloys. FIG. 1 illustrates the structure of a zinc blende alloy. In general, a zinc blende alloy has a face centered cubic-like structure with the Group III atoms occupying the corners and the faces of the cube and the Group V atoms occupying the interstitial spaces within the cube, positioned between the Group III atoms. This results in a unit cell having four group III atoms (4×1=4) and four Group V atoms (6×0.5+8×0.125=4).

FIG. 1 illustrates the nomenclature and notation used to define the three dimensions of a three-dimensional zinc blende crystal structure. The three reference axes, representing the three spatial dimensions are x, y, and z. Directions along any of these axes can be in the positive or negative direction. The positive directions, relative to the origin, are referred to as [100] for the x-axis, [010] for the y-axis, and [001] for the z-axis. The negative directions for each axis are referred to as [−100] for the x-axis, [0-10] for the y-axis, and [00-1] for the z-axis. Thus, each of these can be viewed as a vector originating from a specific point in space, or origin, with each vector having a direction and magnitude. The infinite number of other directions originating from the origin are defined in terms of [100] (the x-axis), [010] (the y-axis), and [001] the (z-axis). For example, referring again to FIG. 1, the [111] direction is indicated, as is the [1-10] direction.

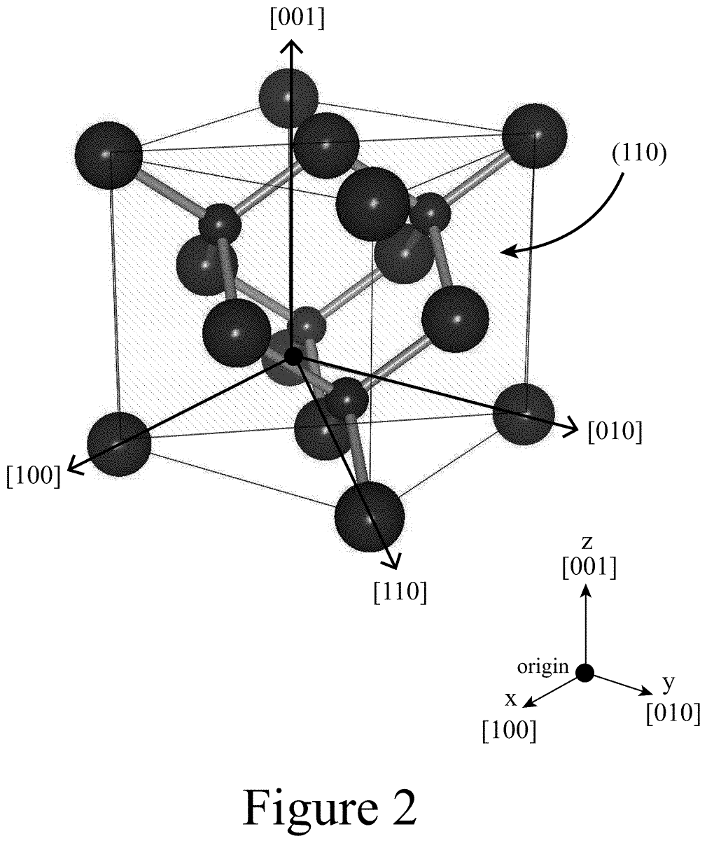

FIG. 2 illustrates how planes within a zinc blende crystal structure are defined and named. In short, a plane is any plane orthogonal to a specific direction. For example, referring to FIG. 2, the direction [110] is indicated, extending from the origin. The plane (110) is positioned perpendicular to the [110] direction and is illustrated as the shaded area. Planes can have families, indicated as {abc}, where planes of the same family are parallel to the other members of the family. Thus, the family for the (110) plane is indicated herein as {110}.

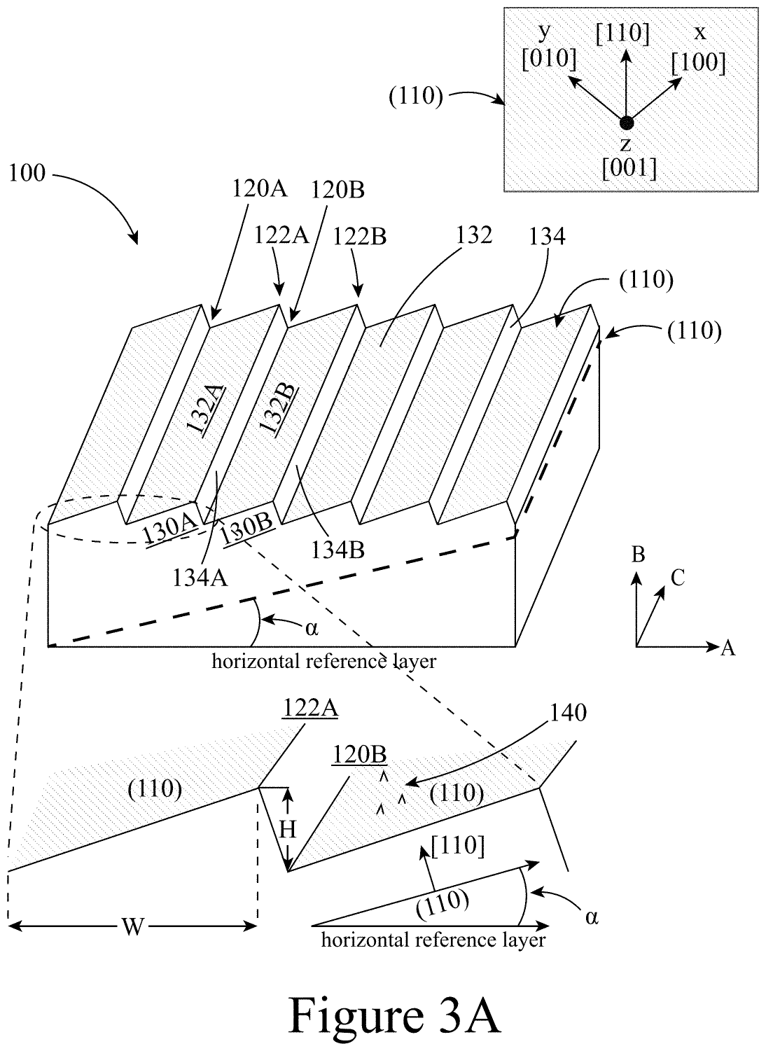

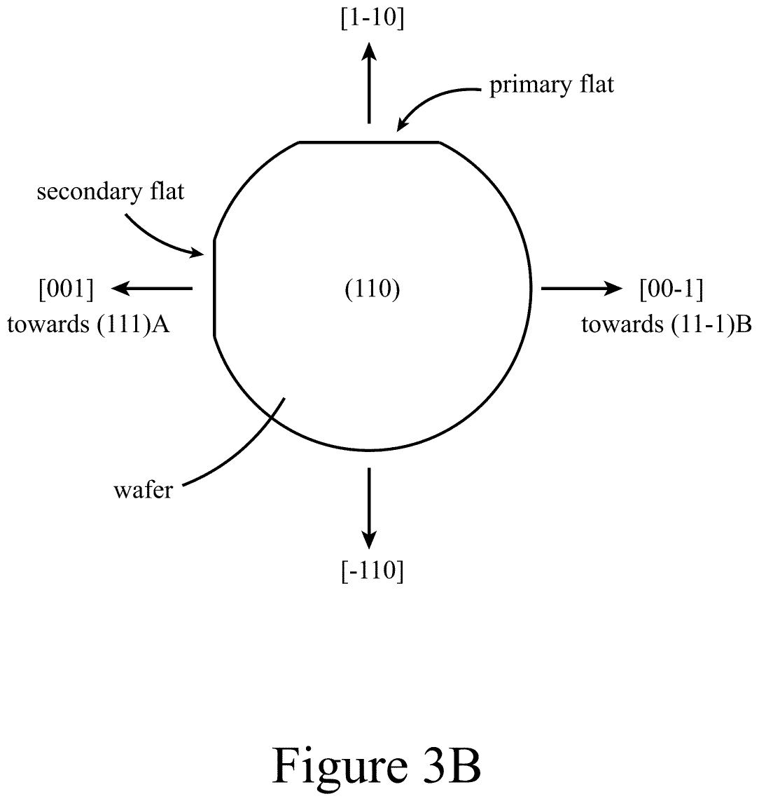

FIG. 3A illustrates a device 100 (i.e., a spalled planar substrate) constructed of a III-V alloy, for example a GaAs wafer (non-bracketed numbers are reference numerals indicating specific features; bracketed numbers indicate directions and planes, as described above). In this example, the device is planar with its surface oriented substantially parallel to the (110) plane, where the (110) plane is indicated by the dashed line in the thickness of the device 100. By “substantially”, the (110) plane is tilted slightly relative to a device having a surface perfectly horizontal. This perfectly horizontal plane is indicated in FIG. 3A as the “horizontal reference plane”, which is synonymous with “reference plane”. This tilt is measured as the angle from reference plane, and is referred to herein as “offcut”, represented by the symbol α. The offcut indicated in FIG. 3A is referred to herein as a positive offcut. If the offcut angle tilts below horizontal, the offcut is referred to herein as negative offcut. However, this is simply a naming convention. A structure having a negative offcut, when rotated 180° in space in the reference plane, would be viewed as having a positive offcut. As shown herein, the direction of offcut (e.g., positive (A) or negative (B)) does not affect the spalling behavior or the properties of the resultant spalled substrate. Only the magnitude of the offcut, α, was found to impact the spalling behavior and the resultant surface properties of the resultant spalled substrate (see FIG. 3A).

FIG. 3A illustrates additional features of a device 100 (i.e., a spalled planar substrate), according to some embodiments of the present disclosure. The surface of the device 100 is constructed of a plurality of terraces 130, each constructed of a first surface 132 aligned with (i.e., oriented with), in this example, the (110) plane. Each first surface 132 has a positive offcut, a, relative to the horizontal reference plane. The first surface 132 of each terrace 130 is positioned between a pair of boundaries, with a first boundary 120 of a pair positioned at a low point and the second boundary 122 positioned at a high point, each relative to the reference axis B (see FIG. 3A). This distance between a first boundary 120 and the second boundary 122 in the B-axis direction is referred to herein as H (i.e., peak-to-valley height). The distance between a pair of boundaries, between 120 and 122, in the A-axis directed, is referred to herein as W. The first surfaces 132 of adjacent terraces 130 are connected by a second surface 134. Thus, referring to FIG. 3A, a first terrace 130A is connected to a second terrace 130B by the second surface 134A of the first terrace 130A, where the second surface 134A of the first terrace 130A is bounded between the second boundary 122A of the first terrace 130A and the first boundary 120B of the second terrace 130B. A second surface 134 may or may not be aligned perpendicular to the first surface 132 of a terrace 130. Finally, the first surface 132 of a terrace 130 may be further characterized by surface imperfections such as surface facets 140, resulting in a non-pristine, irregular (i.e., not smooth) surface. As described herein, such surface imperfections on the first surface 132 of a terrace 130 may be quantified by measuring the surface roughness and observed by SEM and optical methods. Surface roughness may be measured using atomic force microscopy. FIG. 3B illustrates nomenclature and notation, as used herein, to indicate spalling directions relative to a substrate surface oriented to the (110) plane.

As described herein, a device 100 may be constructed of a III-V alloy. In some embodiments of the present disclosure, a device 100 may be constructed of a III-V alloy having a zinc blende crystal structure. Examples of III-V alloys having a zinc blende crystal structure include GaAs, GaP, InAs, AlAs, AlP, InP, and pseudo-binary combinations of these binary alloys. In some embodiments of the present disclosure, the first surface 134 of a terrace 130 of a device 100 may be positioned at an offcut angle, α, relative to the horizontal reference plane, of less than 5°, less than 4°, less than 3°, less than 2°, or less than 1°. In some embodiments of the present disclosure, the first surface 134 of a terrace 130 may be positioned in the (110) plane or other low index planes such as the (111), (211), and/or (311) planes. In some embodiments of the present disclosure, the distance between a pair of boundaries (120 and 122) in the A-axis directed, W, may be between 1 μm and 1 mm. In some embodiments of the present disclosure, the distance between a first boundary 120 and the second boundary 122 in the B-axis direction, H, may be between greater than 0 μm and 3 μm.

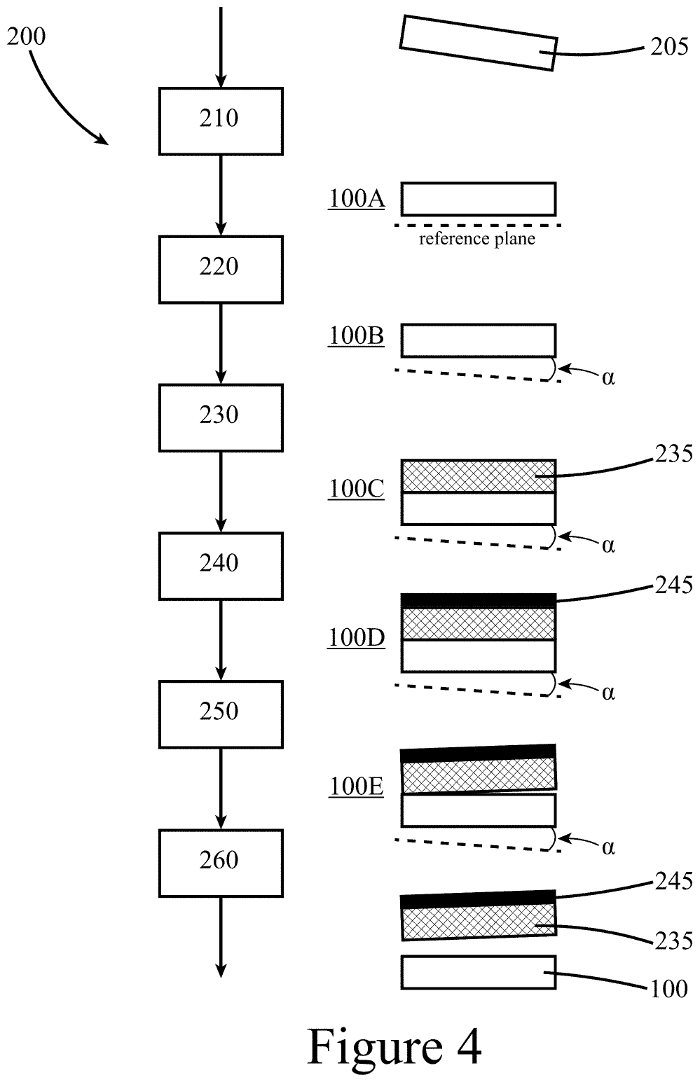

FIG. 4 illustrates a method 200 for manufacturing a device 100 like that illustrated in FIG. 3A. Such a method 200 may begin with a planar substrate 205 and the aligning 210 of the planar substrate 205 with a reference plane, resulting in an aligned planar substrate 100A. For example, a substrate 205 may be provided where its planar surface is substantially the (110) plane of a III-V alloy, e.g., GaAs. This (110) surface may be aligned with the reference plane. Next, the method 200 may continue with the adjusting of the planar substrate 220, resulting in an aligned planar substrate 100B. This adjusting 220 may be performed to provide the offcut, α, desired. For example, a substrate 205 having a (110) surface may be tilted relative to the reference axis by a set number of degrees, α. In some embodiments of the present disclosure, the “adjusting” 220 to achieve the desired offcut, α, may be achieved by physically cutting the substrate 205. Once the offcut, α, has been attained, the method may continue with the depositing 230 of at least one device layer 235 onto the substrate, resulting in device 100C. In some embodiments, of the present disclosure, the depositing 230 of a device layer may be achieved using HYPE. Next, the method may proceed with the depositing 240 of a stressor layer 245 onto the device layer, resulting in device 100D. Once the stressor layer 245 has been deposited, the device 100D may be subjected to the applying 250 of a directional force to the surface of the stressor layer, resulting in the formation and propagation of a crack at or near to the device layer 235/planar substrate 205 interface as shown by device 100E. In some embodiments of the present disclosure, the propagation of a crack may occur just below the original outer surface of planar substrate 205. The application of a force to the stressor layer 245 ultimately results in the separating 260 of the device layer 100 from the stressor layer 245 and the device layer 235. Subsequently, the stressor layer 245 may be separated from the device layer 235 (not shown) so that the device layer 235 may undergo further processing for the production of a final product (e.g., solar cell, light-emitting diode, etc.). The recovered planar substrate (i.e., device 100) may then be recycled and reused to produce additional device layers.

As shown herein, GaAs solar cells were grown by dynamic-HYPE (D-HPVE) on (110)-oriented GaAs substrates, which demonstrated equivalent performance and material quality relative to D-HVPE grown GaAs solar cells grown on (100)-oriented GaAs substrates. Complementing this success, was the successful development and use of a method capable of providing the repeatable wafer-scale spalling of GaAs device layers from their underlying (110)-oriented GaAs substrate layer. The spalled surfaces of the recovered GaAs substrate layers were free of the facets typically found after spalling in recovered (100)-oriented substrates surfaces and free of surface features having greater than 3 μm in peak-to-valley height, which can otherwise degrade the efficiency of subsequent III-V device layers grown on the recovered substrate layer. A sub-μm step-terrace morphology, as described above and illustrated in FIG. 3A, was discovered on the post-spall wafer surface (i.e., substrate surface), resulting from the restricted cleavage system of a (110)-oriented GaAs substrate layer.

Further, an understanding was developed of the factors that determine the resulting step-terrace morphology, enabling ample opportunity for optimization of morphologies suitable for device growth, as well as minimizing the amount of GaAs wasted in post-spalling treatment steps to smooth the spalled surfaces. In addition, as described herein, a solar cell device was successfully grown on a previously spalled (110)-oriented GaAs substrate surface. The resultant devices exhibited a relative efficiency difference of only about 8% relative to a control solar cell grown on a new unspalled (110)-oriented GaAs substrate surface. These results highlight the promise of (110)-oriented devices coupled with substrate reuse by spalling as a pathway for low-cost III-V photovoltaics.

Device efficiency is the most direct way to evaluate whether the quality of material grown on HYPE-ready and as-spalled surfaces can sustain high quality devices. As shown herein, a 15% efficiency baseline was demonstrated in a device structure including a (110)-oriented GaAs substrate layer and a doped GaInP device layer, as well as their integration into a complete device with suitable quality. Demonstration of efficiencies within 15% (relative) in at least one device utilizing a spalled (110)-oriented GaAs substrate shows that major hurdles to regrowth on spalled surfaces do not exist. Overall, this validates the potential for both high-efficiency (110) devices as well as a viable low-cost pathway for substrate reuse on this platform.

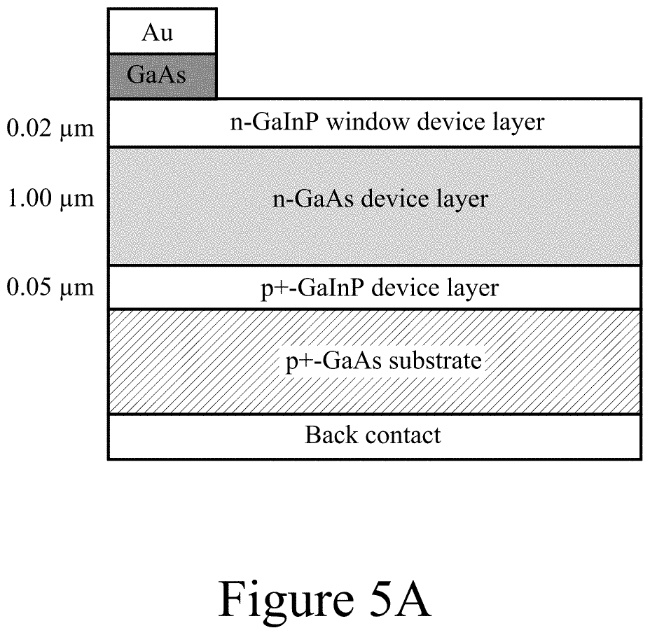

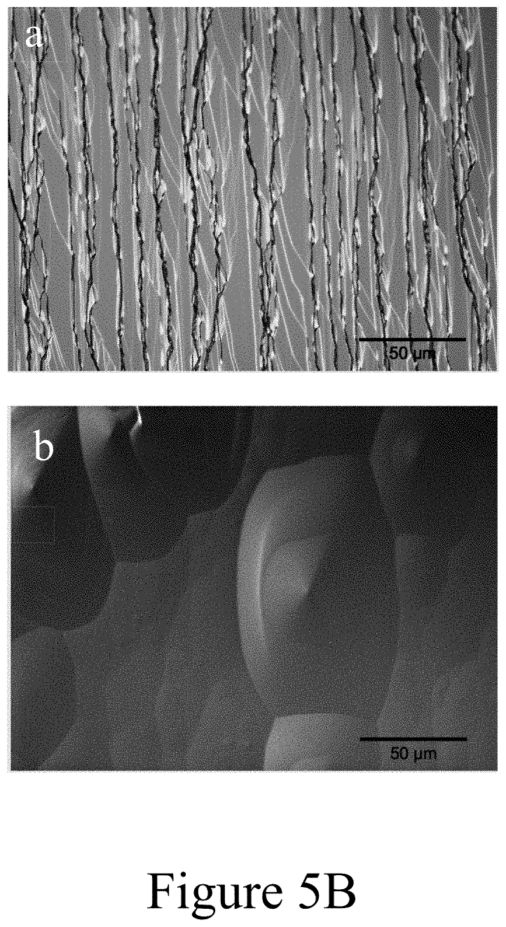

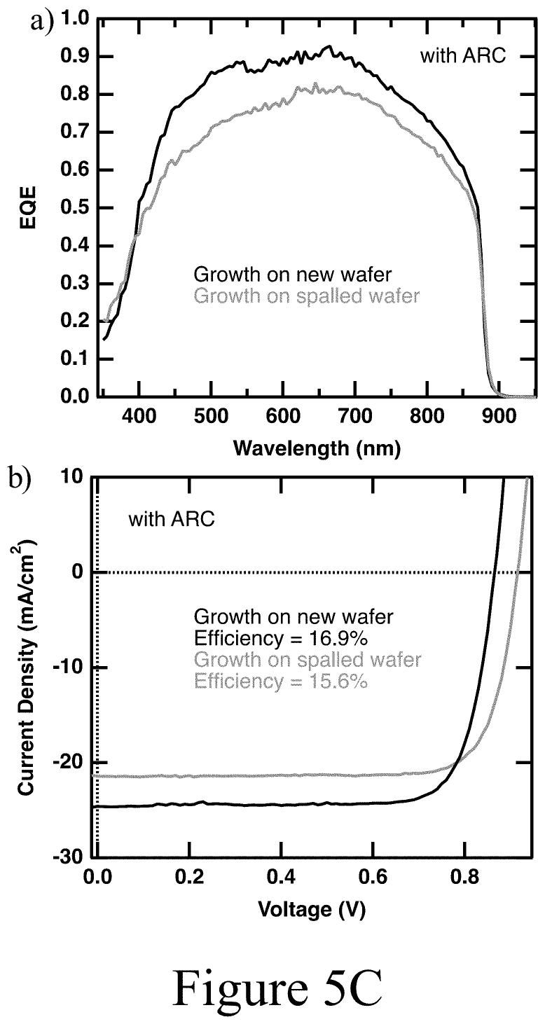

So, in more detail, to evaluate the effect of growing device layers on a (110)-oriented GaAs substrate on device performance (e.g., a solar cell), a complete device stack having the architecture shown in Panel (a) of FIG. 5A was constructed. Panel (a) of FIG. 5B illustrates the surface of a (110)-oriented GaAs substrate wafer (i.e., substrate) used for the regrowth after spalling and Panel (b) of FIG. 5B illustrates the surface after regrowth, which illustrates the presence of surface hillocks that were not present in growth on a new, non-spalled wafer. This result suggests that learning how to nucleate and grow on spalled surfaces is important to future development of this technology. The spalled (110)-oriented GaAs substrate wafer underwent no processing before re-growth, except for being dipped in a Ni-selective etchant to remove residual Ni left over from the spalling process. The etchant does not chemically etch the GaAs. Panel (a) of FIG. 5C illustrates the external quantum efficiency of upright devices grown on a previously spalled wafer and a control device grown on brand new non-spalled wafer. The device grown on the spalled (110)-oriented GaAs substrate exhibits a reduced external quantum efficiency (EQE) relative to the control, implying a reduced carrier diffusion length in the spalled wafer device. Thus, this device has a lower short-circuit current density than the control device. However, comparing the current density-voltage curves of each device (see Panel (b) of FIG. 5C), both devices have an efficiency above the 15% threshold, and the spalled wafer device is within ˜7% relative efficiency of the control device.

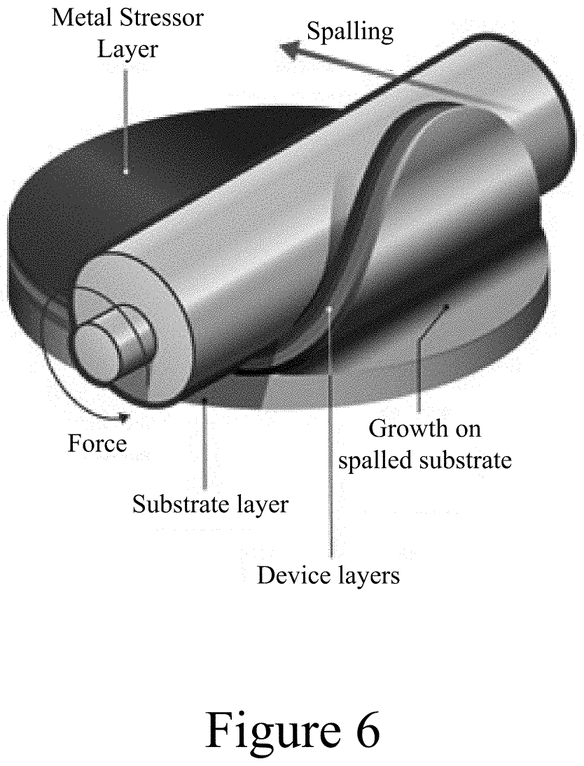

An example of controlled spalling (i.e., separating, exfoliation) is illustrated in FIG. 6. In some embodiments, as shown in FIG. 6, controlled spalling (step 250 of applying a directional force illustrated in FIG. 4) can be achieved by depositing a stressor layer onto the device or substrate surface (step 240 of depositing of stressor layer onto device layer illustrated in FIG. 4). The deposition of the stressor layer onto the device/substrate surface results in the formation of a residual tensile stress within the device/substrate at some distance below the surface of the stressor layer, close-to, but just below the critical fracture toughness, K_{Ic}, of the bulk planar substrate. An externally applied force (e.g., a roller with an adhesive as shown in FIG. 6) is then applied to the stressor layer to initiate and propagate a horizontal crack parallel to the substrate surface at a depth controlled by, among other things, the thickness of the stressor layer.

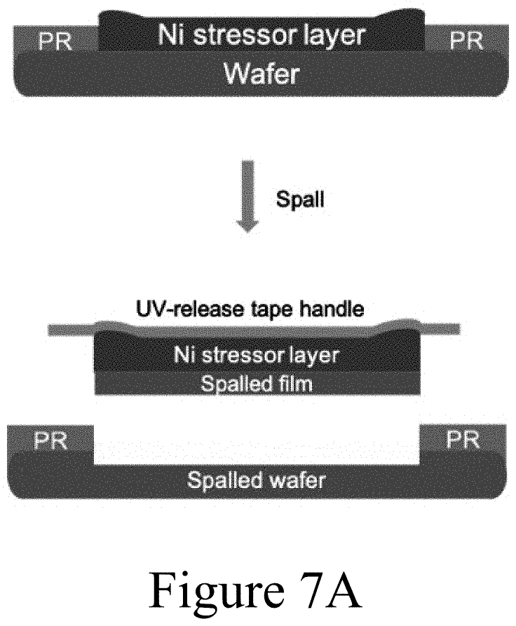

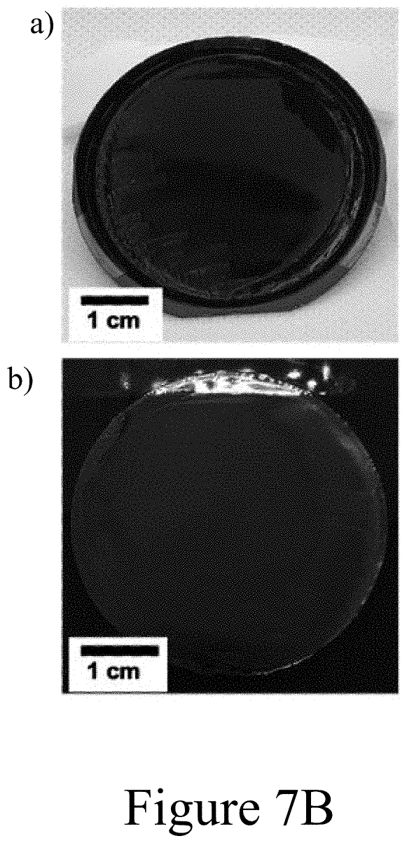

In order for spalling to provide an economical substrate re-use solution, wafer-scale spalls should be demonstrated without significant edge effects that increase roughness and limit the number of achievable spalls per wafer. Therefore, (110)-oriented GaAs substrate wafers with 50-mm diameters were prepared for spalling by electroplating a stressed Ni layer on the surface of the GaAs substrate layers, defined by an edge-adhesion demoter of a photoresist (PR) mask coated on the outer 4 mm of the wafer radius. An area of 14 cm² was spalled from wafers using an automated spalling apparatus. Development of edge-to-edge plating methods may eliminate the need for the demoter in the future. FIG. 7A illustrates an exemplary spalling procedure and FIG. 7B a representative spalled film and wafer.

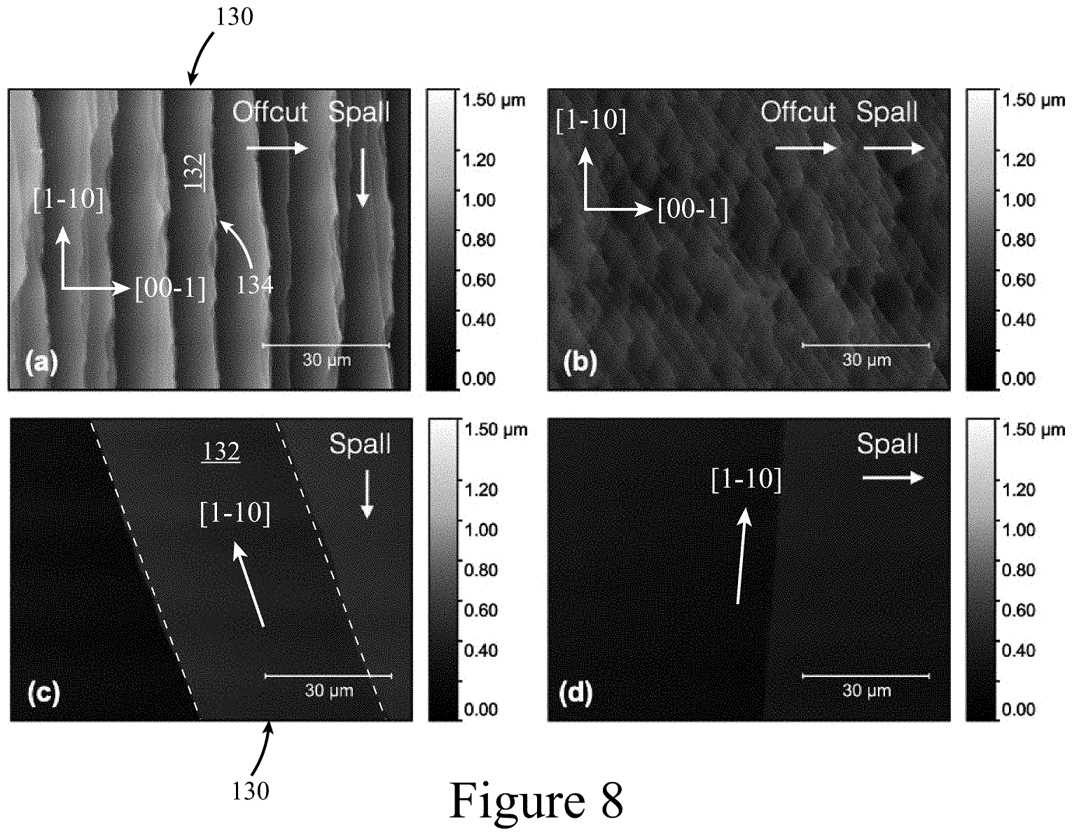

A selective etching procedure was developed to measure the spalled depth of GaAs substrates. A gridded PR mask was applied to the substrate using photolithography and the exposed GaAs was etched. Spalled wafer surfaces were evaluated using laser profilometry, confocal microscopy, and atomic force microscopy (AFM) for surface roughness and topographical features. Crystallographic terraces, features distinct from surface facets and other fracture morphologies were observed on spalled (110)-GaAs samples with a terrace height, H, of between 0.1 μm and 1 μm, with slightly larger heights, H, observed on samples with high wafer offcut angle (1.5°±0.5°, 3°±0.5°). Relatively smooth terraces were observed, positioned in {110} planes with sub-nm roughness. The size of the terraces was determined to be dependent on the offcut angle of the substrate and the spall direction. Substrates with high offcut angle (1.5°±0.5°, 3°±0.5°) produced small terraces from a few microns to 10 s of micrometers in width, W. Substrates cut on-axis within ±0.5° and ±0.05° tolerance produced large terraces tens to hundreds of micrometers in width, W. Spall direction impacted terrace width on substrates with high offcut angles, producing wide parallel terraces when spalling in the [1-10] direction and small irregular terraces when spalling in the [00-1] direction (see FIG. 3B). FIG. 8 compares the morphology of spalled (110) GaAs surfaces by offcut angle and spall direction. The combination of a low substrate offcut and [1-10] spall direction created the smoothest surfaces suitable for regrowth.

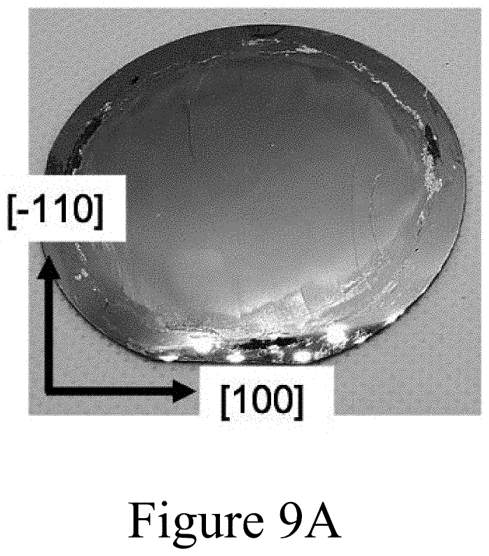

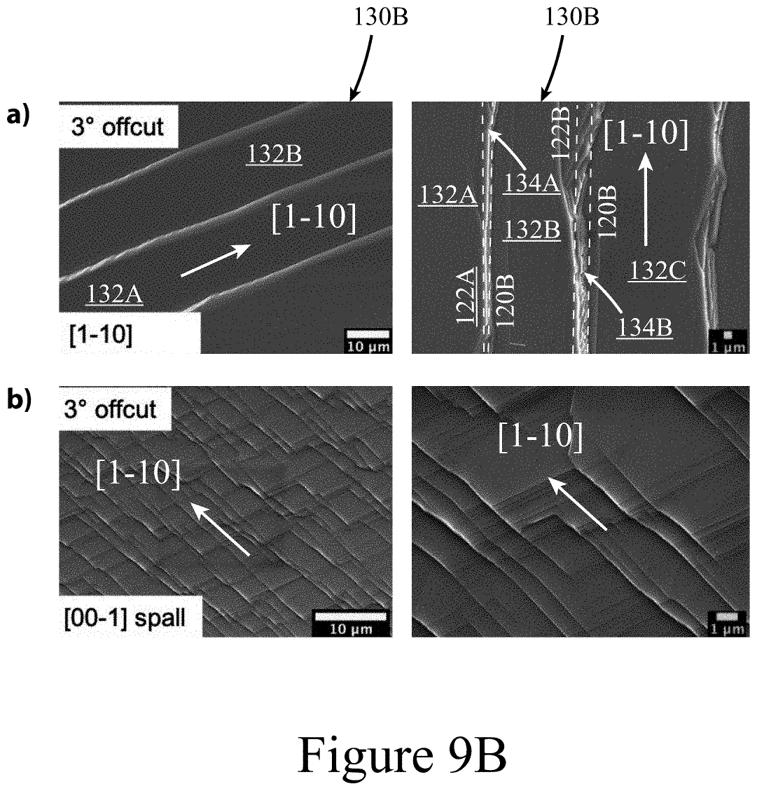

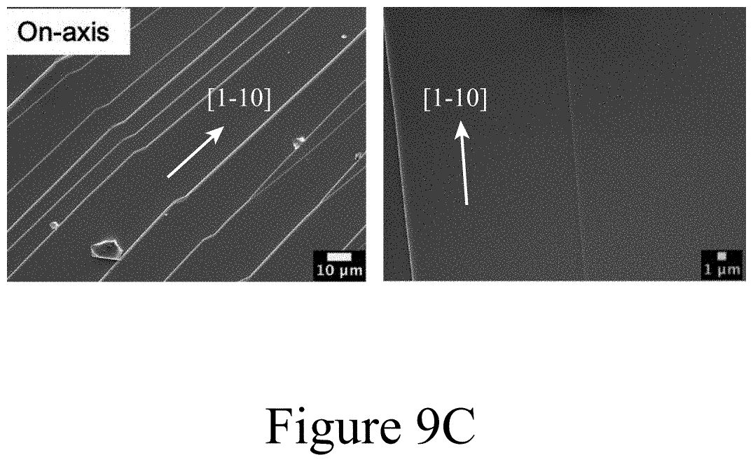

FIGS. 9B and 9C illustrates cross sectional scanning electron microscopy (SEM) images of the resultant surface morphology after using the spalling methods detailed in this work. FIG. 9A illustrates an optical image of a wafer post spall, which defines the primary crystallographic directions of note for a (110) oriented wafer. Panel (a) of FIG. 9B illustrates SEM images of a (110) wafer with a 3° A offcut spalled in the [1-10] direction at two magnifications. Panel (b) FIG. 9B illustrates SEM images of a (110) wafer with a 3° A offcut spalled in the [00-1] direction at two magnifications. FIG. 9C illustrates SEM images of a (110) wafer with nominally no offcut with a misorientation not greater than +or −0.5° off (110) spalled in the [1-10] direction at two magnifications.

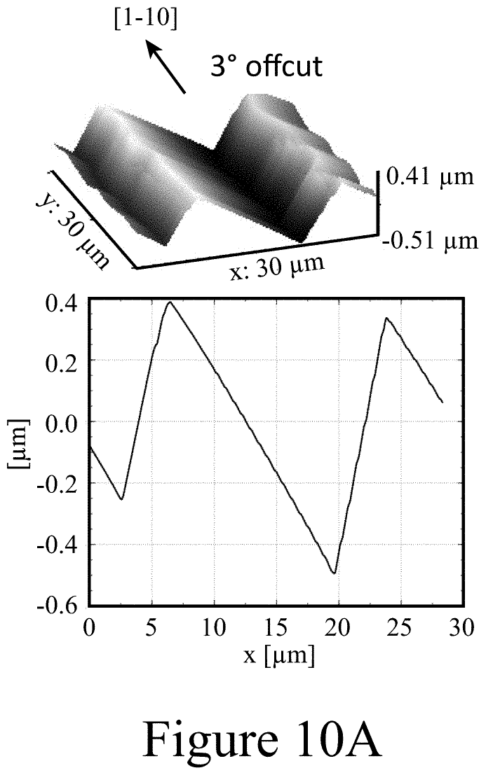

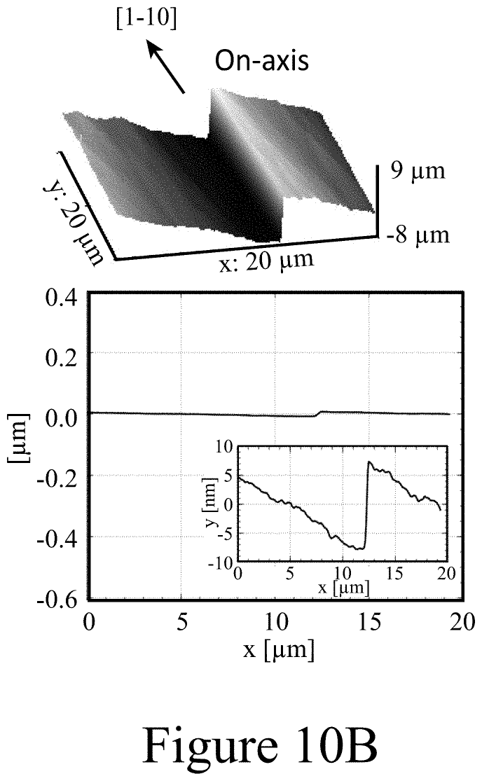

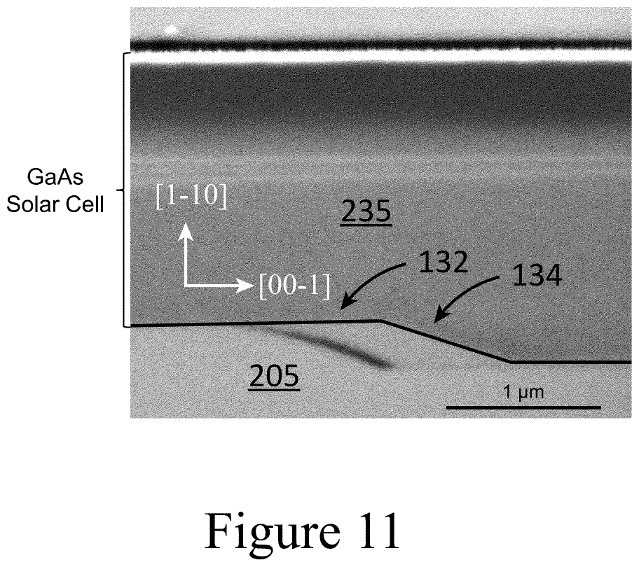

FIGS. 10A and 10B illustrate confocal microscopy images of surface steps formed by spalling of (110) GaAs substrates, according to some embodiments of the present disclosure with: FIG. 10A 3° or FIG. 10B nominally 0° offcut (on-axis) in the [1-10] direction. The spall of the substrate with reduced offcut reduces the step height by nearly an order of magnitude. FIG. 11 illustrates a scanning electron microscopy image of a GaAs solar cell grown by hydride vapor phase epitaxy on a previously spalled (110) GaAs substrate with a 3° offcut, spalled in the [1-10] direction, according to some embodiments of the present disclosure. The epitaxial layers are seen to easily planarize over the sub-μm step in the reused substrate generated by the spall.

The foregoing discussion and examples have been presented for purposes of illustration and description. The foregoing is not intended to limit the aspects, embodiments, or configurations to the form or forms disclosed herein. In the foregoing Detailed Description for example, various features of the aspects, embodiments, or configurations are grouped together in one or more embodiments, configurations, or aspects for the purpose of streamlining the disclosure. The features of the aspects, embodiments, or configurations, may be combined in alternate aspects, embodiments, or configurations other than those discussed above. This method of disclosure is not to be interpreted as reflecting an intention that the aspects, embodiments, or configurations require more features than are expressly recited in each claim. Rather, as the following claims reflect, inventive aspects lie in less than all features of a single foregoing disclosed embodiment, configuration, or aspect. While certain aspects of conventional technology have been discussed to facilitate disclosure of some embodiments of the present invention, the Applicants in no way disclaim these technical aspects, and it is contemplated that the claimed invention may encompass one or more of the conventional technical aspects discussed herein. Thus, the following claims are hereby incorporated into this Detailed Description, with each claim standing on its own as a separate aspect, embodiment, or configuration.

What is claimed is:

1. A composition comprising:
a III-V planar substrate having a surface aligned with and parallel to a reference plane, wherein:
the surface comprises a plurality of terraces,
each terrace comprises a first surface positioned between a first boundary and a second boundary,
each boundary is substantially parallel to the other boundaries and positioned substantially parallel to the reference plane,
each terrace is separated from an adjacent terrace by a second surface positioned between the second boundary of the terrace and the first boundary of the adjacent terrace,
for each terrace, the first boundary is positioned approximately at a distance, H, relative to its second boundary in a first direction that is orthogonal to the reference plane,
for each terrace, the first boundary is positioned approximately at a distance, W, relative to the second boundary in a second direction parallel to the reference plane and orthogonal to the first direction,
each terrace is positioned in a plane that is positioned at an angle, α, relative to the reference plane,
each terrace has a surface roughness of less than 1 nm, as measured by atomic force microscopy,
0 μm≤H≤3 μm, and 1 μm<W≤1 mm.

2. The composition of claim 1, wherein H varies between ±20%.

3. The composition of claim 1, wherein W varies between ±15%.

4. The composition of claim 1, wherein the III-V planar substrate has a zinc blende crystal structure.

5. The composition of claim 4, wherein the III-V planar substrate is constructed of at least one of GaAs, GaP, InAs, AlAs, AlP, or InP.

6. The composition of claim 4, wherein the III-V planar substrate is constructed of a pseudo-binary combinations of at least one of GaAs, GaP, InAs, AlAs, AlP, or InP.

7. The composition of claim 1, wherein a is between less than 5°.

8. The composition of claim 1, wherein a is between less than 3°.

9. The composition of claim 1, wherein each terrace is positioned substantially in at least one of the (110) plane, the (111) plane, the (211) plane, or the (311) plane.

10. The composition of claim 1, wherein 30 μm<W≤100 μm.

11. A method comprising:
depositing a device layer onto a planar substrate;
depositing a stressor layer onto the device layer; and
applying a directional force orthogonal to the reference plane and moving in a direction that is parallel to the reference plane, wherein:
the planar substrate is oriented to a plane is that is positioned at an angle, α, relative to a reference plane, and
the applying results in the separating of the device layer from at least a portion of the planar substrate.

12. The method of claim 11, wherein the planar substrate is substantially oriented in at least one of the (110) plane, the (111) plane, the (211) plane, or the (311) plane.

13. The method of claim 11, wherein the planar substrate is composed of a III-V alloy having a zinc blende crystal structure.

14. The method of claim 11, wherein the angle α is less than 5°.

15. The method of claim 11, wherein the angle α is less than 3°.

16. The method of claim 11, wherein the planar substrate is substantially oriented in the (110) plane and the moving of the directional force is substantially in the [1-10] direction.

17. The method of claim 11, wherein the separating of the device layer occurs at thickness, t, of less than 10 μm into the planar substrate relative to an interface created by the planar substrate and the device layer.

18. The method of claim 17, wherein the thickness into the planar substrate is 3 μm≤t<10 μm.

19. The method of claim 11, wherein the applying is achieved using a roller configured with an adhesive.

20. The method of claim 11, further comprising recovering and recycling the separated planar substrate for at least one additional depositing of a device layer.
